(19) United States
(12) Patent Application Publication
(10) Pub. No.: US 2025/0159950 A1
(43) Pub. Date: May 15, 2025

(54) DUAL SIDE CUT STAGGERED STACKED FIELD EFFECT TRANSISTOR

(71) Applicant: INTERNATIONAL BUSINESS MACHINES CORPORATION, ARMONK, NY (US)

(72) Inventors: Ruilong Xie, Niskayuna, NY (US); Chen Zhang, Santa Clara, CA (US); Junli Wang, Slingerlands, NY (US); Kisik Choi, Watervliet, NY (US)

(21) Appl. No.: 18/508,475

(22) Filed: Nov. 14, 2023

(51) Int. Cl. H01L 29/06; H01L 21/8238; H01L 27/092; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/151; H10D 64/017; H10D 84/0177; H10D 84/038; H10D 84/85

(57) ABSTRACT

According to the embodiment of the present invention, a semiconductor device includes a plurality of nanodevices including a plurality of upper transistors and a plurality of lower transistors. The plurality of nanodevices include an upper active region and a lower active region that are offset from each other across the plurality of upper transistors and the plurality of lower transistors. A first frontside gate cut dielectric pillar is located adjacent to and parallel to a first nanodevice of the plurality of nanodevices along an x-axis. A backside surface of the first frontside gate cut dielectric pillar extends a first width along a y-axis. A first backside dielectric fill is in direct contact with the backside surface of the first frontside gate cut dielectric pillar. A frontside surface of the first backside dielectric fill extends a second width along the y-axis. The second width is greater than the first width.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to the embodiment of the present invention, a semiconductor device includes a plurality of nanodevices including a plurality of upper transistors and a plurality of lower transistors. The plurality of nanodevices include an upper active region and a lower active region that are offset from each other across the plurality of upper transistors and the plurality of lower transistors. A first frontside gate cut dielectric pillar is located adjacent to and parallel to a first nanodevice of the plurality of nanodevices along an x-axis. A backside surface of the first frontside gate cut dielectric pillar extends a first width along a y-axis. A first backside dielectric fill is in direct contact with the backside surface of the first frontside gate cut dielectric pillar. A frontside surface of the first backside dielectric fill extends a second width along the y-axis. The second width is greater than the first width.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIGS. 2-4 illustrate cross sections X, Y1, and Y2, respectively, of the plurality of nanodevices after interlayer dielectric (ILD) deposition, nanosheet formation, shallow trench isolation (STI) region formation, gate formation, gate spacer and inner spacer formation, bottom dielectric isolation (BDI) layer formation, middle dielectric isolation (MDI) layer formation, source/drain formation, etch stop layer formation, self-aligned contact (SAC) cap formation, and CMP, in accordance with the embodiment of the present invention.

FIG. 5 illustrates a top-down view of the plurality of nanodevices after the formation of a first trench, a second trench, and a third trench, in accordance with the embodiment of the present invention.

FIGS. 6-8 illustrate cross sections X, Y1, and Y2, respectively, of the plurality of nanodevices after the formation of the first trench, the second trench, and the third trench, in accordance with the embodiment of the present invention.

FIG. 9 illustrates a top-down view of the plurality of nanodevices after the formation of a first frontside gate cut dielectric pillar, a second frontside gate cut dielectric pillar, a first frontside dielectric liner, a second frontside dielectric liner, and a frontside dielectric fill, in accordance with the embodiment of the present invention.

FIGS. 10-12 illustrate cross sections X, Y1, and Y2, respectively, of the plurality of nanodevices after the formation of the first frontside gate cut dielectric pillar, the second frontside gate cut dielectric pillar, the first frontside dielectric liner, the second frontside dielectric liner, and the frontside dielectric fill, in accordance with the embodiment of the present invention.

FIGS. 13-15 illustrate cross sections X, Y1, and Y2, respectively, of the plurality of nanodevices after the formation of a lower source/drain contact, a source/drain contact, a plurality of gate contacts, a back-end-of-line (BEOL) layer, and bonding to a carrier wafer, in accordance with the embodiment of the present invention.

FIGS. 16-18 illustrate cross sections X, Y1, and Y2, respectively, of the plurality of nanodevices after the carrier wafer is flipped and the substrate is removed, in accordance with the embodiment of the present invention.

FIGS. 19-21 illustrate cross sections X, Y1, and Y2, respectively, of the plurality of nanodevices after the removal of the etch stop layer and the underlying substrate layer, in accordance with the embodiment of the present invention.

FIGS. 22-24 illustrate cross sections X, Y1, and Y2, respectively, of the plurality of nanodevices after backside ILD (BILD) layer deposition and CMP, in accordance with the embodiment of the present invention.

FIGS. 25-27 illustrate cross sections X, Y1, and Y2, respectively, of the plurality of nanodevices after the formation of a fourth trench, a fifth trench, and a sixth trench, in accordance with the embodiment of the present invention.

FIGS. 28-30 illustrate cross sections X, Y1, and Y2, respectively, of the plurality of nanodevices after the formation of a backside gate cut dielectric pillar, a first backside dielectric liner, a second backside dielectric liner, a first backside dielectric fill, and a second backside dielectric fill, in accordance with the embodiment of the present invention.

FIGS. 31-33 illustrate cross sections X, Y1, and Y2, respectively, of the plurality of nanodevices after the formation of a plurality of backside source/drain contacts, an upper source/drain contact, and a backside power delivery network (BSPDN), in accordance with the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

Clause 1. A semiconductor device includes a plurality of nanodevices including a plurality of upper transistors and a plurality of lower transistors, where the plurality of nanodevices include an upper active region and a lower active region that are offset from each other across the plurality of upper transistors and the plurality of lower transistors. A first frontside gate cut dielectric pillar is located adjacent to and parallel to a first nanodevice of the plurality of nanodevices along an x-axis, where a backside surface of the first frontside gate cut dielectric pillar extends a first width along a y-axis. A first backside dielectric fill is in direct contact with the backside surface of the first frontside gate cut dielectric pillar, where a frontside surface of the first backside dielectric fill extends a second width along the y-axis, and where the second width is greater than the first width.

Clause 2. The semiconductor device of clause 1, where the upper active region may include a plurality of upper nanosheets and the lower active region may include a plurality of lower nanosheets, where the plurality of upper nanosheets may be located closer to the first frontside gate cut dielectric pillar than the plurality of lower nanosheets.

Clause 3. The semiconductor device of any of the preceding clauses, where the plurality of upper nanosheets and the plurality of lower nanosheets may be offset from each other across the plurality of upper transistors and the plurality of lower transistors.

Clause 4. The semiconductor device of any of the preceding clauses, where the semiconductor device may comprise a first frontside dielectric liner extending along first inner sidewalls of the plurality of upper nanosheets and a second frontside dielectric liner extending along second inner sidewalls of the plurality of upper nanosheets. A frontside dielectric fill may be located between the first frontside dielectric liner and the second frontside dielectric liner.

Clause 5. The semiconductor device of any of the preceding clauses, where the semiconductor device may further comprise a backside gate cut dielectric pillar in direct contact with a backside surface of the frontside dielectric fill.

Clause 6. The semiconductor device of any of the preceding clauses, where the first frontside dielectric liner, the second frontside dielectric liner, the first frontside gate cut dielectric pillar, and the backside gate cut dielectric pillar may be comprised of a same dielectric material, and where the first backside dielectric fill and the frontside dielectric fill may be comprised of a different dielectric material.

Clause 7. The semiconductor device of any of the preceding clauses, where the first frontside gate cut dielectric pillar and the backside gate cut dielectric pillar may be offset from each other across the plurality of upper transistors and the plurality of lower transistors.

Clause 8. The semiconductor device of any of the preceding clauses, where the backside surface of the frontside dielectric fill may extend a third width along the y-axis, where a frontside surface of the backside gate cut dielectric pillar may extend a fourth width along the y-axis, and where the third width may be greater than the fourth width.

Clause 9. A semiconductor device includes a plurality of nanodevices including a plurality of upper transistors and a plurality of lower transistors, where the plurality of nanodevices include an upper active region and a lower active region that are offset from each other across the plurality of upper transistors and the plurality of lower transistors. A first frontside gate cut dielectric pillar and a second frontside gate cut dielectric pillar are located adjacent to and parallel to a first nanodevice and a second nanodevice, respectively, of the plurality of nanodevices along an x-axis, where a backside surface of the first frontside gate cut dielectric pillar and a backside surface of the second frontside gate cut dielectric pillar each extend a first width along a y-axis. A first backside dielectric fill and a second backside dielectric fill are in direct contact with the backside surface of the first frontside gate cut dielectric pillar and the backside surface of the second frontside gate cut dielectric pillar, respectively, where a frontside surface of the first backside dielectric fill and a frontside surface of the second backside dielectric fill each extend a second width along the y-axis, wherein the second width is greater than the first width.

Clause 10, the semiconductor device of any of the preceding clauses, where the upper active region may include a plurality of upper nanosheets and the lower active region may include a plurality of lower nanosheets, where the plurality of upper nanosheets may be located closer to the first frontside gate cut dielectric pillar than the plurality of lower nanosheets.

Clause 11. The semiconductor device of any of the preceding clauses, where the plurality of upper nanosheets and the plurality of lower nanosheets may be offset from each other across the plurality of upper transistors and the plurality of lower transistors.

Clause 12. The semiconductor device of any of the preceding clauses, where the semiconductor device may further comprise a first frontside dielectric liner extending along first inner sidewalls of the plurality of upper nanosheets and a second frontside dielectric liner extending along second inner sidewalls of the plurality of upper nanosheets. A frontside dielectric fill may be located between the first frontside dielectric liner and the second frontside dielectric liner.

Clause 13. The semiconductor device of any of the preceding clauses, where the semiconductor device may further comprise a backside gate cut dielectric pillar in direct contact with a backside surface of the frontside dielectric fill. A first backside dielectric liner and a second backside dielectric liner may be located along an inner sidewall of the second backside dielectric fill and an inner sidewall of the first backside dielectric fill, respectively, where the first frontside dielectric liner and the second backside dielectric liner may be offset from each other across the plurality of upper transistors and the plurality of lower transistors, and where the second frontside dielectric liner and the first backside dielectric liner may be offset from each other across the plurality of upper transistors and the plurality of lower transistors.

Clause 14. The semiconductor device of any of the preceding clauses, where the first frontside dielectric liner, the second frontside dielectric liner, the first frontside gate cut dielectric pillar, the second frontside gate cut dielectric pillar, the first backside gate cut dielectric pillar, the second backside gate cut dielectric pillar, and the backside gate cut dielectric pillar may be comprised of a same dielectric material, and where the first backside dielectric fill, the second backside dielectric fill, and the frontside dielectric fill may be comprised of a different dielectric material.

Clause 15. The semiconductor device of any of the preceding clauses, where the frontside dielectric fill and the first backside dielectric fill may be offset from each other across the plurality of upper transistors and the plurality of lower transistors, and where the frontside dielectric fill and the second backside dielectric fill may be offset from each other across the plurality of upper transistors and the plurality of lower transistors.

Clause 16. The semiconductor device of any of the preceding clauses, where the first frontside gate cut dielectric pillar and the backside gate cut dielectric pillar may be offset from each other across the plurality of upper transistors and the plurality of lower transistors, and where the second frontside gate cut dielectric pillar and the backside gate cut dielectric pillar may be offset from each other across the plurality of upper transistors and the plurality of lower transistors.

Clause 17. A semiconductor device includes a plurality of nanodevices including a plurality of upper transistors and a plurality of lower transistors, where the plurality of nanodevices include an upper active region and a lower active region that are offset from each other across the plurality of upper transistors and the plurality of lower transistors, where the upper active region includes an upper source/drain, and where the lower active region includes a lower source/drain. A first frontside gate cut dielectric pillar and a second frontside gate cut dielectric pillar are located adjacent to and parallel to a first nanodevice and a second nanodevice, respectively, of the plurality of nanodevices along an x-axis, where a backside surface of the first frontside gate cut dielectric pillar and a backside surface of the second frontside gate cut dielectric pillar each extend a first width along a y-axis. A first backside dielectric fill and a second backside dielectric fill are in direct contact with the backside surface of the first frontside gate cut dielectric pillar and the backside surface of the second frontside gate cut dielectric pillar, respectively, where a frontside surface of the first backside dielectric fill and a frontside surface of the second backside dielectric fill each extend a second width along the y-axis, wherein the second width is greater than the first width.

Clause 18. The semiconductor device of any of the preceding clauses, where the upper source/drain and the lower source/drain may be offset from each other across the plurality of upper transistors and the plurality of lower transistors.

Clause 19. The semiconductor device of any of the preceding clauses, where the upper active region may further include a plurality of upper nanosheets and the lower active region may further include a plurality of lower nanosheets, where the plurality of upper nanosheets may be located closer to the first frontside gate cut dielectric pillar than the plurality of lower nanosheets.

Clause 20. The semiconductor device of any of the preceding clauses, where the plurality of upper nanosheets and the plurality of lower nanosheets may be offset from each other across the plurality of upper transistors and the plurality of lower transistors.

Clause 21. The semiconductor device of any of the preceding clauses, where the semiconductor device may further comprise a first frontside dielectric liner extending along first inner sidewalls of the plurality of upper nanosheets and a second frontside dielectric liner extending along second inner sidewalls of the plurality of upper nanosheets. A frontside dielectric fill may be located between the first frontside dielectric liner and the second frontside dielectric liner.

Clause 22. The semiconductor device of any of the preceding clauses, where the semiconductor device may further comprise a backside gate cut dielectric pillar in direct contact with a backside surface of the frontside dielectric fill. A first backside dielectric liner and a second backside dielectric liner may be located along an inner sidewall of the second backside dielectric fill and an inner sidewall of the first backside dielectric fill, respectively, where the first frontside dielectric liner and the second backside dielectric liner may be offset from each other across the plurality of upper transistors and the plurality of lower transistors, and where the second frontside dielectric liner and the first backside dielectric liner may be offset from each other across the plurality of upper transistors and the plurality of lower transistors.

Clause 23. The semiconductor device of any of the preceding clauses, where the upper source/drain may be in direct contact with an outer sidewall of the first frontside dielectric liner, and where the lower source/drain may be in direct contact with an inner sidewall of the second backside dielectric liner.

Clause 24. A semiconductor device includes a plurality of nanodevices including a plurality of upper transistors and a plurality of lower transistors, where the plurality of nanodevices include an upper active region and a lower active region that are offset from each other across the plurality of upper transistors and the plurality of lower transistors, where the upper active region includes an upper source/drain, and where the lower active region includes a lower source/drain. An upper source/drain contact and a lower source/drain contact are connected to the upper source/drain and the lower source/drain, respectively. A first frontside gate cut dielectric pillar and a second frontside gate cut dielectric pillar are located adjacent to and parallel to a first nanodevice and a second nanodevice, respectively, of the plurality of nanodevices along an x-axis, where a backside surface of the first frontside gate cut dielectric pillar and a backside surface of the second frontside gate cut dielectric pillar each extend a first width along a y-axis. A first backside dielectric fill and a second backside dielectric fill are in direct contact with the backside surface of the first frontside gate cut dielectric pillar and the backside surface of the second frontside gate cut dielectric pillar, respectively, where a frontside surface of the first backside dielectric fill and a frontside surface of the second backside dielectric fill each extend a second width along the y-axis, wherein the second width is greater than the first width.

Clause 25. The semiconductor device of any of the preceding clauses, where the upper source/drain contact may extend downwards from a backside of the plurality of nanodevices to connect to a backside of the upper source/drain, and where the lower source/drain contact may extend upwards from a frontside of the plurality of nanodevices to connect to a frontside of the lower source/drain.

When a via to the backside power rail (VBPR) extends downwards from a frontside contact the via may be located between two active regions on a nanodevice. Stacked field effect transistor (FET) scaling is limited by the deep VBPR connections. A staggered stacked FET removes the need of the deep VBPR. However, in a staggered stacked FET arrangement, a bonded flow is needed, and for a contacted poly pitch of 45 nanometers (nm) with a contact size of about 12 nm, a 3 nanometer (nm) gate misalignment results in about a 25% contact area reduction. Thus, it is unfavorable to implement a staggered stacked FET scheme using a bonded flow.

By employing a monolithic flow with a single gate patterning, the risk of a gate misalignment may be prevented. The present invention does not require that all advantages need to be incorporated into every embodiment of the invention.

The present invention is directed to forming a staggered stacked FET such that active regions of upper and lower transistors are offset from each other. The staggered stacked FET is formed through a multistage processing, where the first stage forms a first trench by etching a portion of the gates, a self-aligned contact (SAC) cap, an interlayer dielectric (ILD), upper source/drains, and upper nanosheets; and a second and a third trench by etching a portion of the SAC cap and the gates. The second stage forms a first frontside dielectric liner, a second frontside dielectric liner, and a frontside dielectric fill inside the first trench, and fills the second trench and the third trench with a dielectric material to form frontside gate cut dielectric pillars through the gates and the ILD. The third stage forms a source/drain contact within the ILD and the dielectric fill along an inner sidewall of the first frontside dielectric liner. The fourth stage forms a fourth trench by etching a portion of a shallow trench isolation (STI) region, the ILD, and the gates; and a fifth and a sixth trench by etching a portion of the gates, the ILD, a backside ILD (BILD) layer, lower source/drains, lower nanosheets, a bottom dielectric isolation (BDI) layer, and a middle dielectric isolation (MDI) layer. The fifth stage fills the fourth trench with the dielectric material to form the backside gate cut dielectric pillar through the gates and the ILD. The fifth stage also forms a first backside dielectric liner and a first backside dielectric fill inside the fifth trench, and a second backside dielectric liner and a second backside dielectric fill inside the sixth trench. The sixth stage forms a backside source/drain contact within the second backside dielectric fill and the ILD along an outer sidewall of the second backside dielectric liner.

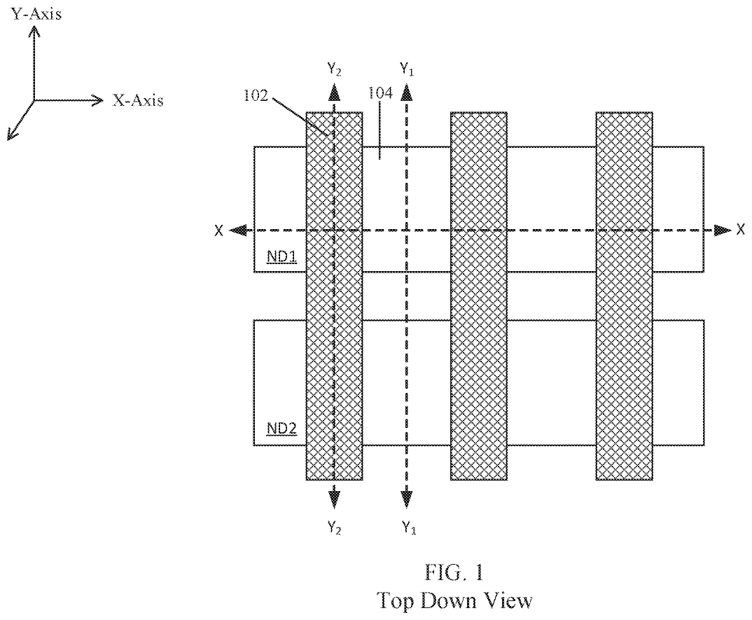

FIG. 1 illustrates a top-down view of a plurality of nanodevices ND1, ND2, in accordance with the embodiment of the present invention. The adjacent and parallel devices along an x-axis include a first nanodevice ND1 and a second nanodevice ND2 including a plurality of upper transistors and a plurality of lower transistors. Cross-section X is a cross section perpendicular to the gates along the horizontal axis of the first nanodevice ND1. Cross-section Y1 is a cross section parallel to the gates in the source/drain region 104 across the plurality of nanodevices ND1, ND2. Cross-section Y2 is a cross section parallel to the gates in the gate region 102 across the plurality of nanodevices ND1, ND2. It may be appreciated that the embodiment of the present invention is not limited to nanodevices ND1, ND2 and that other devices including, but not limited to, nanosheet transistors, FinFET, nanowire, and a planar device may also be used.

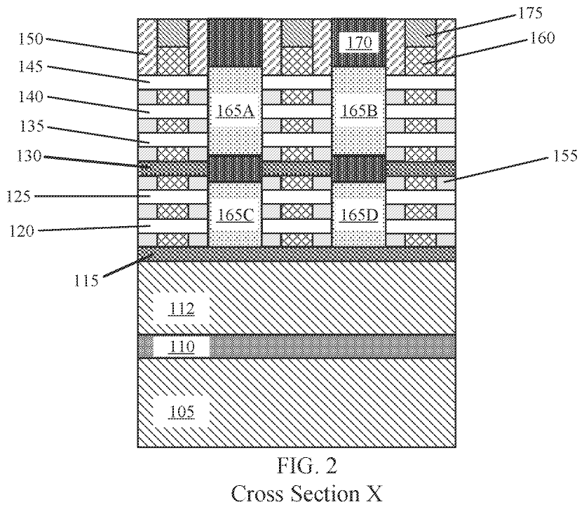

FIGS. 2-4 illustrate cross sections X, Y1, and Y2, respectively, of the plurality of nanodevices ND1, ND2 after interlayer dielectric (ILD) 170 deposition, nanosheet 120, 125, 135, 140, 145 formation, shallow trench isolation (STI) region 114 formation, gate 160 formation, gate spacer 150 and inner spacer 155 formation, bottom dielectric isolation (BDI) layer 115 formation, middle dielectric isolation (MDI) layer 130 formation, source/drain 165A, 165B, 165C, 165D, 165E, 165F formation, etch stop layer 110 formation, self-aligned contact (SAC) cap 175 formation, and CMP, in accordance with the embodiment of the present invention. The plurality of nanodevices ND1, ND2 include a substrate 105, an etch stop layer 110, an underlying substrate layer 112, an STI region 114, a first lower nanosheet 120, a second lower nanosheet 125, a first upper nanosheet 135, a second upper nanosheet 140, and a third upper nanosheet 145. As used herein, the terms “upper” and “lower” refer to the orientation of structures prior to a wafer flip. Thus, structures above the MDI layer 130 prior to the wafer flip are referred to as “upper” and structures below the MDI layer 130 prior to the wafer flip are referred to as “lower.” The substrate 105 and the etch stop layer 110 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 and the etch stop layer 110 may be doped, undoped or contain doped regions and undoped regions therein.

The first sacrificial layer (not shown) is formed directly atop the underlying substrate layer 112. The second sacrificial layer (not shown) is formed directly atop the first sacrificial layer (not shown). The first lower nanosheet 120 is formed directly atop the second sacrificial layer (not shown). The third sacrificial layer (not shown) is formed directly atop the first lower nanosheet 120. The second lower nanosheet 125 is formed directly atop the third sacrificial layer (not shown). The fourth sacrificial layer (not shown) is formed directly atop the second lower nanosheet 125. The MDI layer 130 is formed directly atop the fourth sacrificial layer (not shown). The fifth sacrificial layer (not shown) is formed directly atop the MDI layer 130. The first upper nanosheet 135 is formed directly atop the fifth sacrificial layer (not shown). The sixth sacrificial layer (not shown) is formed directly atop the first upper nanosheet 135. The second upper nanosheet 140 is formed directly atop the sixth sacrificial layer (not shown). The seventh sacrificial layer (not shown) is formed directly atop the second upper nanosheet 140. The third upper nanosheet 145 is formed directly atop the seventh sacrificial layer (not shown). The first sacrificial layer (not shown), the second sacrificial layer (not shown), the third sacrificial layer (not shown), the fourth sacrificial layer (not shown), the fifth sacrificial layer (not shown), the sixth sacrificial layer (not shown), and the seventh sacrificial layer (not shown) are hereinafter referred to as the plurality of sacrificial layers (not shown). In addition, the first lower nanosheet 120 and the second lower nanosheet 125 are hereinafter referred to as the plurality of lower nanosheets 120, 125, and the first upper nanosheet 135, the second upper nanosheet 140, and the third upper nanosheet 145 are hereinafter referred to as the plurality of upper nanosheets 135, 140, 145. The plurality of sacrificial layers (not shown) may be comprised of, for example, SiGe, where Ge is about 35%. The plurality of lower nanosheets 120, 125 and the plurality of upper nanosheets 135, 140, 145 may be comprised of, for example, Si. The number of nanosheets and the number of sacrificial layers described above are not intended to be limiting, and it may be appreciated that in the embodiment of the present invention the number of nanosheets and the number of sacrificial layers may vary. After formation of the plurality of lower nanosheets 120, 125, the plurality of upper nanosheets 135, 140, 145, and the plurality of sacrificial layers (not shown), together the nanosheet stack, the nanosheet stack (comprising alternative Si and SiGe layers) may be further patterned using conventional lithography and etching processes. After nanosheet stack formation and patterning, the STI region 114 is formed by dielectric filling, CMP, and dielectric recess.

A dummy gate material is deposited and then patterned to form dummy gates (not shown), followed by gate spacer 150 and BDI layer 115 formation by a conformal dielectric liner deposition followed by anisotropic etch. The BDI layer 115 is located directly atop the underlying substrate layer 112. Then, the nanosheet stack at the S/D region 104 is recessed, followed by indentation of sacrificial layers (not shown) and inner spacer 155 formation. Then, the first upper source/drain 165A, the second upper source/drain 165B, the first lower source/drain 165C, the second lower source/drain 165D, the third upper source/drain 165E, and the third lower source/drain 165F are epitaxially grown over exposed sidewalls of the plurality of lower nanosheets 120, 125 and the plurality of upper nanosheets 135, 140, 145, followed by ILD 170 deposition and CMP to remove a dummy gate hard mask (not shown). Then, the sacrificial layers (not shown) are removed, followed by gate 160 formation. The first lower source/drain 165C, the second lower source/drain 165D, and the third lower source/drain 165F are formed directly atop the BDI layer 115. The first upper source/drain 165A (i.e., the upper source/drain in the claims), the second upper source/drain 165B, and the third upper source/drain 165E are formed over the first lower source/drain 165C (i.e., the lower source drain in the claims), the second lower source/drain 165D, and the third lower source/drain 165F, respectively, within the ILD 170.

The first upper source/drain 165A, the second upper source/drain 165B, the first lower source/drain 165C, the second lower source/drain 165D, the third upper source/drain 165E, and the third lower source/drain 165F can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (TI) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

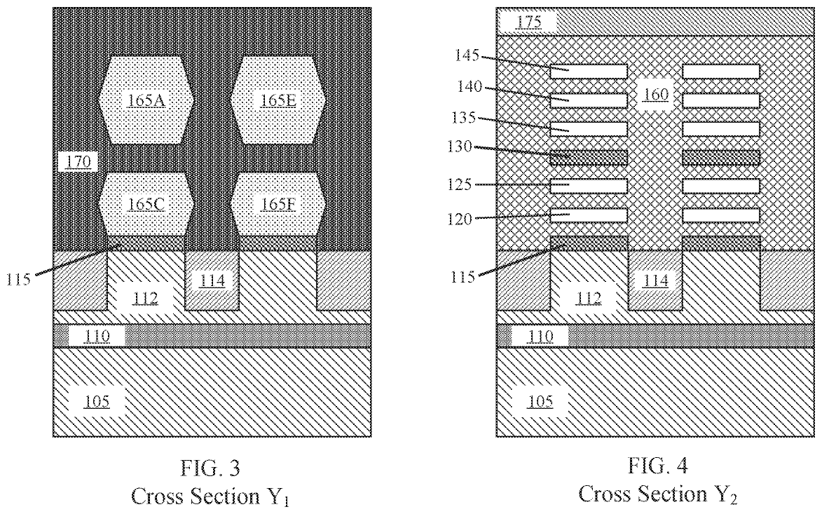

In FIG. 2, the ILD 170 is formed directly atop the first upper source/drain 165A, the second upper source/drain 165B, the first lower source/drain 165C, and the second lower source/drain 165D, and surrounds one side of the gate spacer 150, the MDI layer 130, and a portion of the inner spacer 155. In FIG. 3, the ILD 170 is formed directly atop the first upper source/drain 165A, the first lower source/drain 165C, the third upper source/drain 165E and the third lower source/drain 165F, and the STI region 114.

In FIG. 2, a gate material is deposited in the space created by the removal of the plurality of sacrificial layers (not shown) and directly atop the third upper nanosheet 145 to form a replacement gate (i.e., the gate 160). In FIG. 4, the gate material is deposited in the space created by the removal of the plurality of sacrificial layers (not shown), and directly atop the third upper nanosheet 145 and the STI region 114 to form the gate 160. The gate 160 can be comprised of, for example, a gate dielectric liner, such as a high-k dielectric like HfO2, ZrO2, HfLaOx, etc., and work function layers, such as TiN, TiAlC, TiC, etc., and conductive metal fills, like W. In FIGS. 2 and 4, a dielectric material is deposited directly atop the gate 160 to form the SAC cap 175.

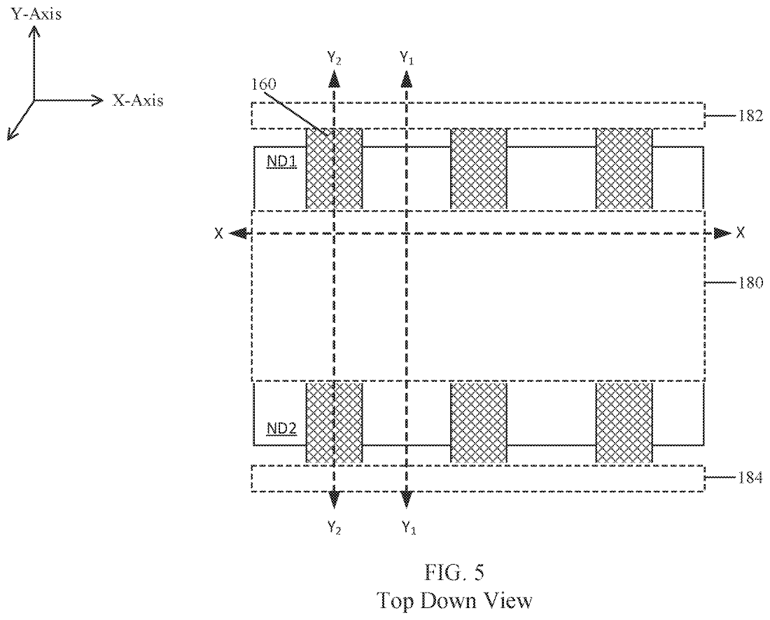

FIG. 5 illustrates a top-down view of the plurality of nanodevices ND1, ND2 after the formation of a first trench 180, a second trench 182, and a third trench 184, in accordance with the embodiment of the present invention. FIG. 5 is meant to illustrate a cut (i.e., the first trench 180, the second trench 182, and the third trench 184) in the gate region 102 (FIG. 1) between the first nanodevice ND1 and the second nanodevice ND2, and at a cell boundary of the first nanodevice ND1 and the second nanodevice ND2.

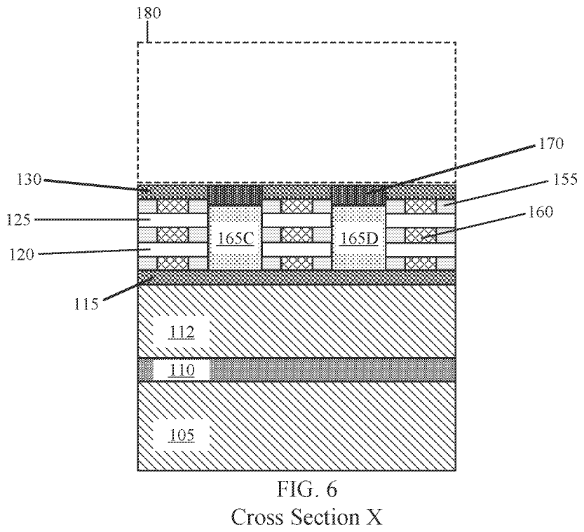

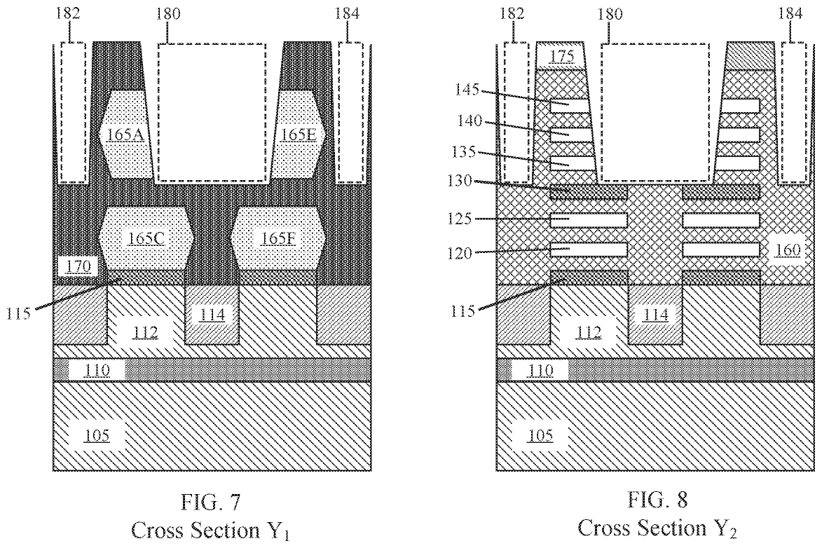

FIGS. 6-8 illustrate cross sections X, Y1, and Y2, respectively, of the plurality of nanodevices ND1, ND2 after the formation of the first trench 180, the second trench 182, and the third trench 184, in accordance with the embodiment of the present invention. In FIG. 6, the first upper source/drain 165A, the second upper source/drain 165B, the SAC cap 175, the plurality of upper nanosheets 135, 140, 145, and a portion of the ILD 170 and the gate 160 are etched by, for example, RIE to form the first trench 180. A bottom surface of the first trench 180 exposes a top surface of the ILD 170 and the MDI layer 130. In FIG. 7, a portion of the ILD 170, the first upper source/drain 165A, and the third upper source/drain 165E are etched by, for example, RIE to form the first trench 180. A bottom surface of the first trench 180 exposes a portion of a top surface of the ILD 170. Different portions of the ILD 170 are etched by, for example, RIE to form the second trench 182 and the third trench 184. Bottom surfaces of the second trench 182 and the third trench 184 expose different portions of the top surface of the ILD 170. In FIG. 8, a portion of the SAC cap 175, the gate 160, and the plurality of upper nanosheets 135, 140, 145 are etched by, for example, RIE to form the first trench 180. A bottom surface of the first trench 180 exposes a portion of a top surface of the gate 160 and the MDI layer 130. Different portions of the SAC cap 175 and the gate 160 are etched by, for example, RIE to form the second trench 182 and the third trench 184. Bottom surfaces of the second trench 182 and the third trench 184 expose different portions of the top surface of the gate 160.

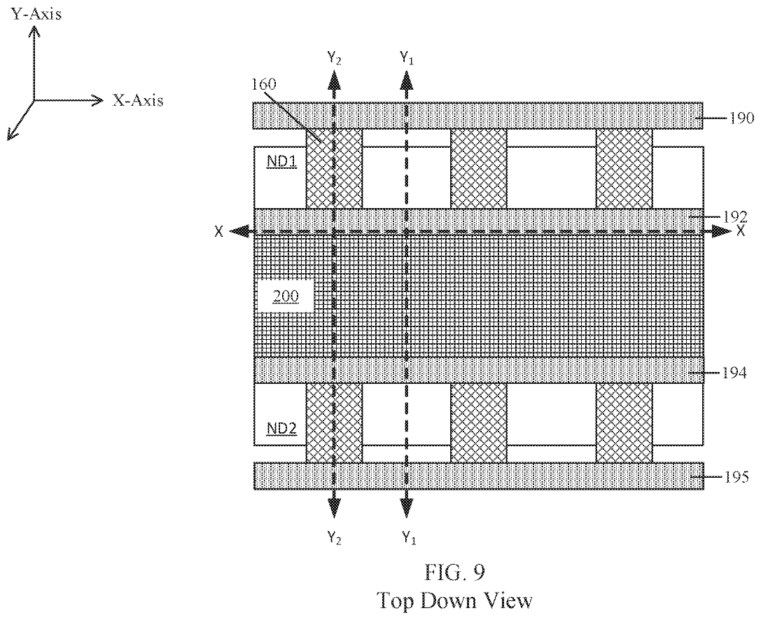

FIG. 9 illustrates a top-down view of the plurality of nanodevices ND1, ND2 after the formation of a first frontside gate cut dielectric pillar 190, a second frontside gate cut dielectric pillar 195, a first frontside dielectric liner 192, a second frontside dielectric liner 194, and a frontside dielectric fill 200, in accordance with the embodiment of the present invention. FIG. 9 is meant to illustrate a cut in the gate region 102 (FIG. 1) that is filled to form the first frontside gate cut dielectric pillar 190, the second frontside gate cut dielectric pillar 195, the first frontside dielectric liner 192, the second frontside dielectric liner 194, and the frontside dielectric fill 200. The first frontside gate cut dielectric pillar 190 is located adjacent to and parallel to the first nanodevice ND1 along the x-axis. The second frontside gate cut dielectric pillar 195 is located adjacent to and parallel to the second nanodevice ND2 along the x-axis.

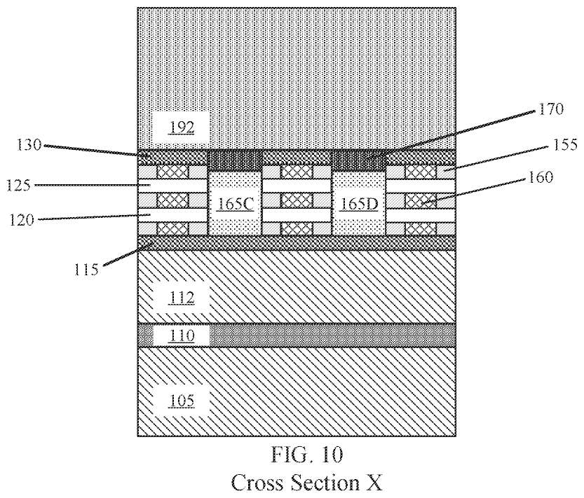

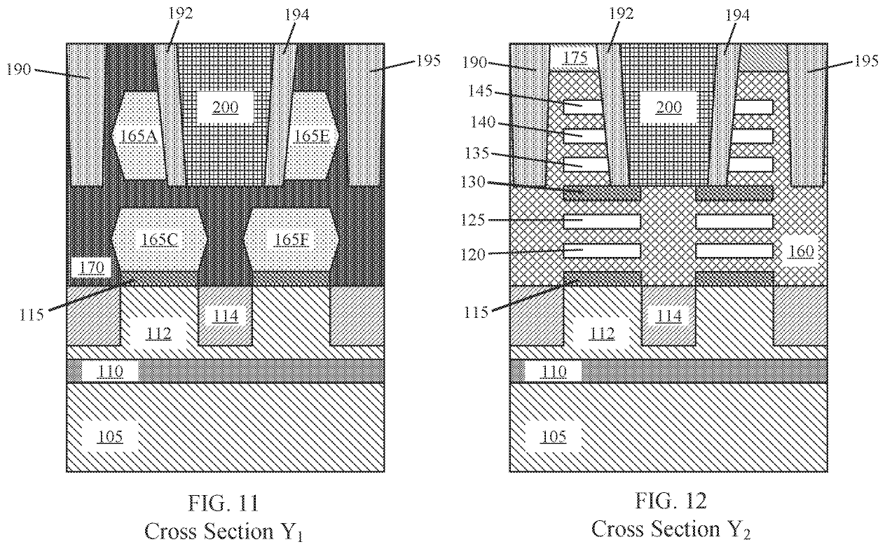

FIGS. 10-12 illustrate cross sections X, Y1, and Y2, respectively, of the plurality of nanodevices ND1, ND2 after the formation of the first frontside gate cut dielectric pillar 190, the second frontside gate cut dielectric pillar 195, the first frontside dielectric liner 192, the second frontside dielectric liner 194, and the frontside dielectric fill 200, in accordance with the embodiment of the present invention. A liner material is deposited in the first trench 180 and etched back to form the first frontside dielectric liner 192 and the second frontside dielectric liner 194 located on the sidewalls of the first trench 180. The liner material is also deposited in the second trench 182 and the third trench 184 to form the first frontside gate cut dielectric pillar 190 and the second frontside gate cut dielectric pillar 195, respectively. The liner material may be comprised of, for example, SiN, SiBCN, SiOCN, SiOC, or SiC. In FIG. 10, a portion of the first frontside dielectric liner 192 is selectively removed by, for example, RIE. In FIG. 11, a portion of the first frontside gate cut dielectric pillar 190, the second frontside gate cut dielectric pillar 195, the first frontside dielectric liner 192, and the second frontside dielectric liner 194 are selectively removed by, for example, RIE to expose a top surface of the ILD 170. In FIG. 12, a portion of the first frontside gate cut dielectric pillar 190, the second frontside gate cut dielectric pillar 195, the first frontside dielectric liner 192, and the second frontside dielectric liner 194 are selectively removed by, for example, RIE to expose a top surface of the SAC cap 175. Then, a dielectric fill material is deposited in the first trench 180 to form the frontside dielectric fill 200 located between the first frontside dielectric liner 192 and the second frontside dielectric liner 194. The frontside dielectric fill 200 may be comprised of, for example, SiO₂. In FIG. 15, the first frontside dielectric liner 192 extends along first inner sidewalls of the plurality of upper nanosheets 135, 140, 145. The second frontside dielectric liner 194 extends along second inner sidewalls of the plurality of upper nanosheets 135, 140, 145.

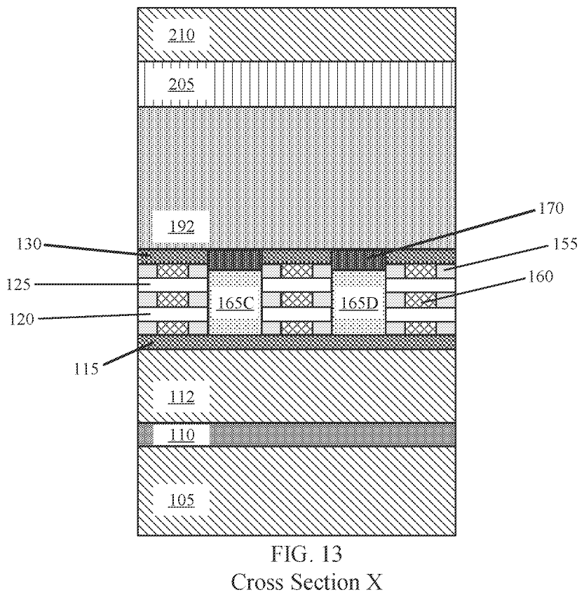

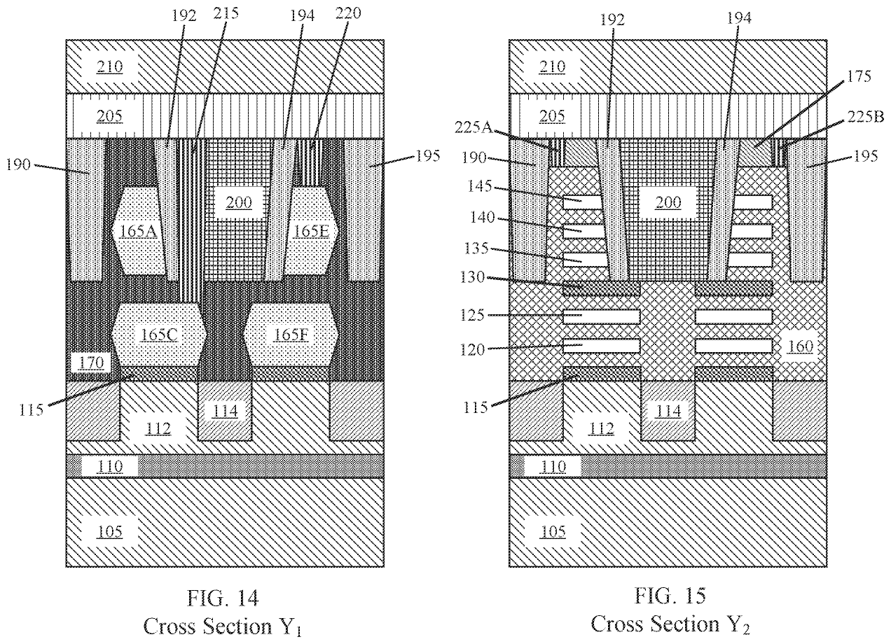

FIGS. 13-15 illustrate cross sections X, Y1, and Y2, respectively, of the plurality of nanodevices ND1, ND2 after the formation of a lower source/drain contact 215, a source/drain contact 220, a plurality of gate contacts 225A, 225B, a back-end-of-line (BEOL) layer 205, and bonding to a carrier wafer 210, in accordance with the embodiment of the present invention. A plurality of trenches (not shown) formed during middle-of-line (MOL) patterning are filled with a conductive metal (e.g., including a silicide liner, such as Ni, Ti, NiPt, an adhesion metal liner, such as TiN and conductive metal fill, such as W, Co, or Ru) to form the lower source/drain contact 215, the source/drain contact 220, and the plurality of gate contacts 225A, 225B. In FIG. 14, the lower source/drain contact 215 is located directly atop the first lower source/drain 165C. The source/drain contact 220 is located directly atop the third upper source/drain 165E. In FIG. 15, the first gate contact 225A is located directly atop the gate 160 between the first frontside gate cut dielectric pillar 190 and the SAC cap 175. The second gate contact 225B is located directly atop the gate 160 between the second frontside gate cut dielectric pillar 195 and the SAC cap 175. The BEOL layer 205 may contain multiple metal layers and vias in between. In FIG. 13, the BEOL layer 205 is formed directly atop the first frontside dielectric liner 192. In FIG. 14, the BEOL layer 205 is formed directly atop the first frontside gate cut dielectric pillar 190, the second frontside gate cut dielectric pillar 195, the first frontside dielectric liner 192, the second frontside dielectric liner 194, the frontside dielectric fill 200, the ILD 170, the lower source/drain contact 215, and the source/drain contact 220. In FIG. 15, the BEOL layer 205 is formed directly atop the first frontside gate cut dielectric pillar 190, the second frontside gate cut dielectric pillar 195, the SAC cap 175, the first gate contact 225A, the second gate contact 225B, the gate 160, the first frontside dielectric liner 192, the second frontside dielectric liner 194, and the frontside dielectric fill 200. In FIGS. 13-15, the carrier wafer 210 is formed directly atop the BEOL layer 205 by bonding processes (e.g., oxide-oxide bonding).

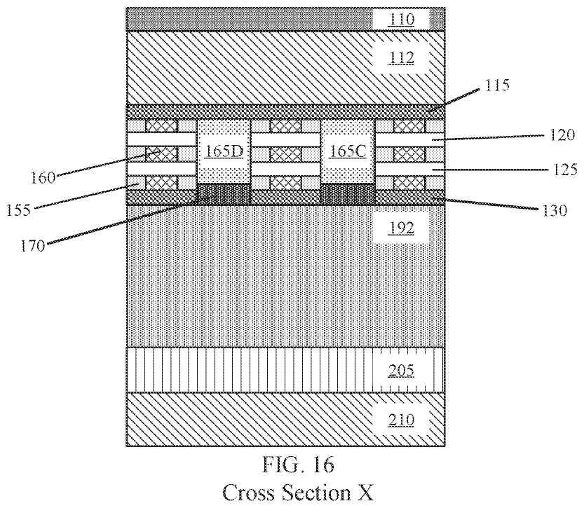

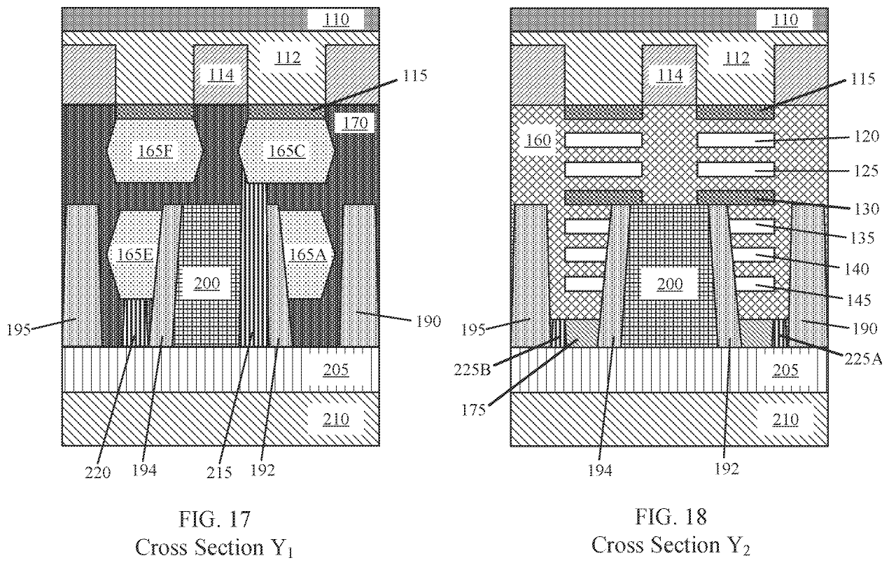

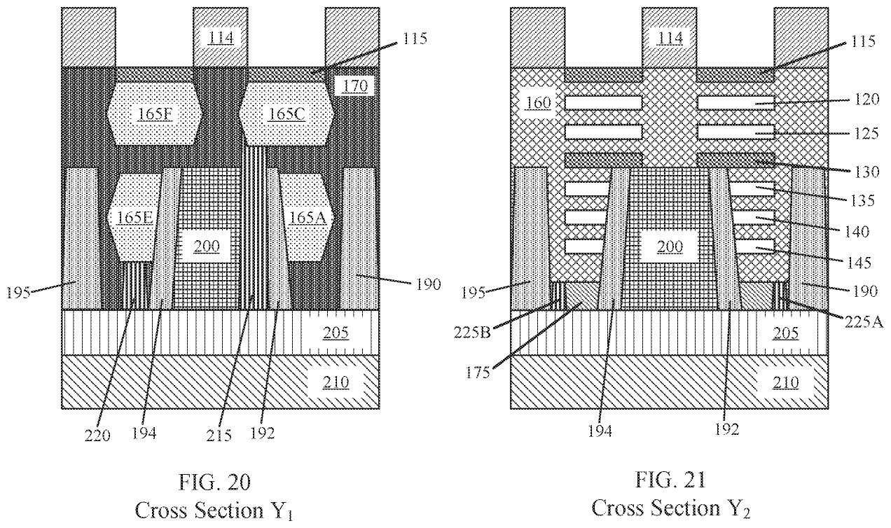

FIGS. 1-15 illustrate the processing of the frontside of the substrate 105, while FIGS. 16-33 illustrate the processing of the backside of the substrate 105. FIGS. 16-18 illustrate cross sections X, Y1, and Y2, respectively, of the plurality of nanodevices ND1, ND2 after the carrier wafer 210 is flipped and the substrate 105 is removed, in accordance with the embodiment of the present invention. The carrier wafer 210 is flipped and the carrier wafer 210 becomes a handler wafer. The substrate 105 is removed by, for example, a combination of processes such as wafer grinding, CMP, and/or selective dry/wet etch, stopping on the etch stop layer 110.

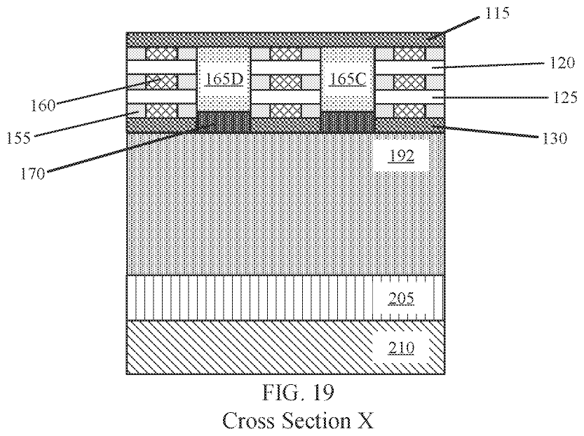

FIGS. 19-21 illustrate cross sections X, Y1, and Y2, respectively, of the plurality of nanodevices ND1, ND2 after the removal of the etch stop layer 110 and the underlying substrate layer 112, in accordance with the embodiment of the present invention. The etch stop layer 110 is removed to expose the underlying substrate layer 112. The underlying substrate layer 112 is removed by, for example, a selective wet or dry etch process.

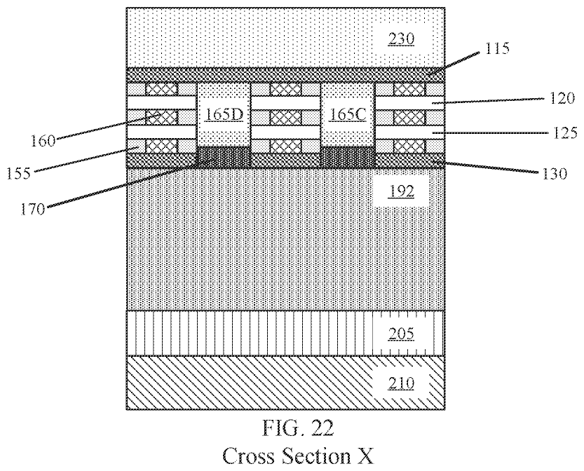

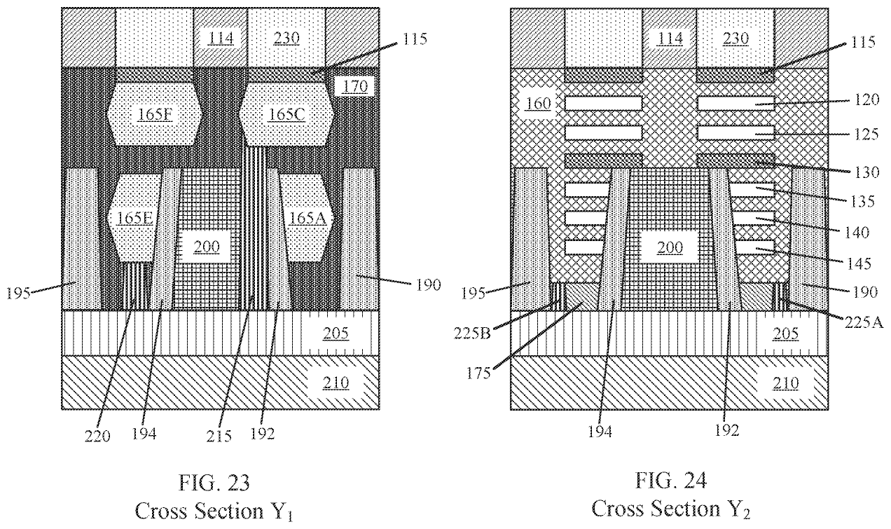

FIGS. 22-24 illustrate cross sections X, Y1, and Y2, respectively, of the plurality of nanodevices ND1, ND2 after backside ILD (BILD) layer 230 deposition and CMP, in accordance with the embodiment of the present invention. The BILD layer 230 may be comprised of, for example, SiC or SiOC. In FIG. 22, the BILD layer 230 is deposited directly atop the BDI layer 115. In FIGS. 23-24, the BILD layer 230 is deposited directly atop the BDI layer 115. In FIGS. 22-24, a portion of the BILD layer 230 is selectively removed by, for example, CMP.

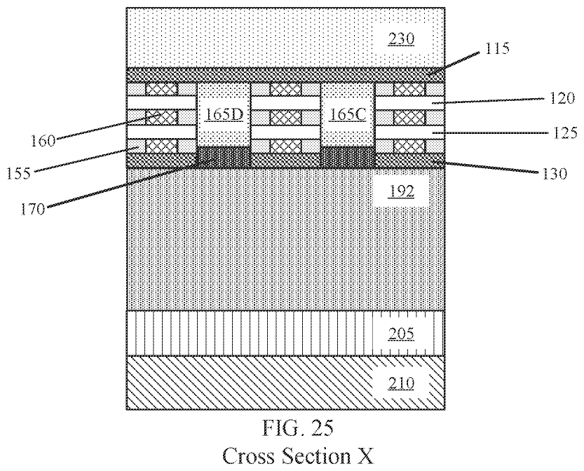

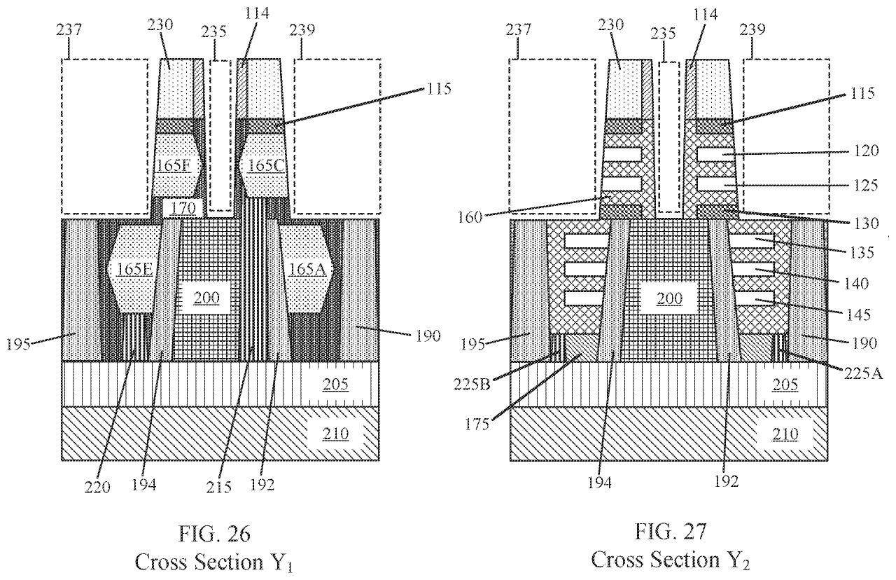

FIGS. 25-27 illustrate cross sections X, Y1, and Y2, respectively, of the plurality of nanodevices ND1, ND2 after the formation of a fourth trench 235, a fifth trench 237, and a sixth trench 239, in accordance with the embodiment of the present invention. In FIG. 26, a portion of the ILD 170, and the STI region 114 are etched by, for example, RIE to form the fourth trench 235. In FIG. 27, a portion of the gate 160 and the STI region 114 are etched by, for example, RIE to form the fourth trench 235. In FIGS. 26-27, a bottom surface of the fourth trench 235 exposes a portion of a top surface of the frontside dielectric fill 200. In FIG. 26, a portion of the ILD 170, the BILD layer 230, the STI region 114, the BDI layer 115, and the third lower source/drain 165F are etched by, for example, RIE to form the fifth trench 237. A bottom surface of the fifth trench 237 exposes a top surface of the second frontside gate cut dielectric pillar 195 and a portion of a top surface of the ILD 170. A portion of the ILD 170, the BILD layer 230, the STI region 114, the BDI layer 115, and the first lower source/drain 165C are etched by, for example, RIE to form the sixth trench 239. A bottom surface of the sixth trench 239 exposes a top surface of the first frontside gate cut dielectric pillar 190 and a portion of the top surface of the ILD 170. In FIG. 27, a portion of the BILD layer 230, the STI region 114, the BDI layer 115, the MDI layer 130, and the gate 160 are etched by, for example, RIE to form the fifth trench 237. The bottom surface of the fifth trench 237 exposes the top surface of the second frontside gate cut dielectric pillar 195 and a portion of the top surface of the gate 160. A portion of the BILD layer 230, the STI region 114, the BDI layer 115, the MDI layer 130, and the gate 160 are etched by, for example, RIE to form the sixth trench 239. The bottom surface of the sixth trench 239 exposes the top surface of the first frontside gate cut dielectric pillar 190 and a portion of the top surface of the gate 160.

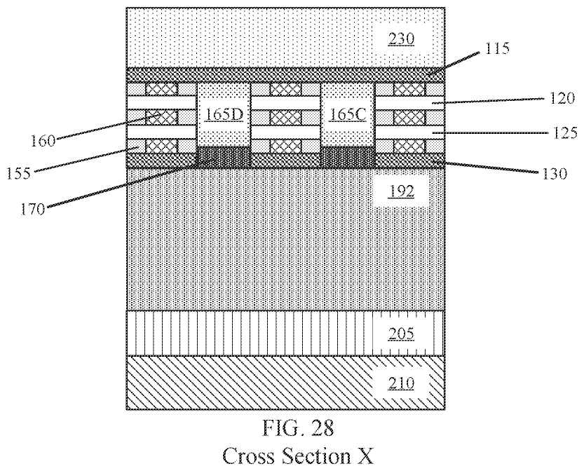

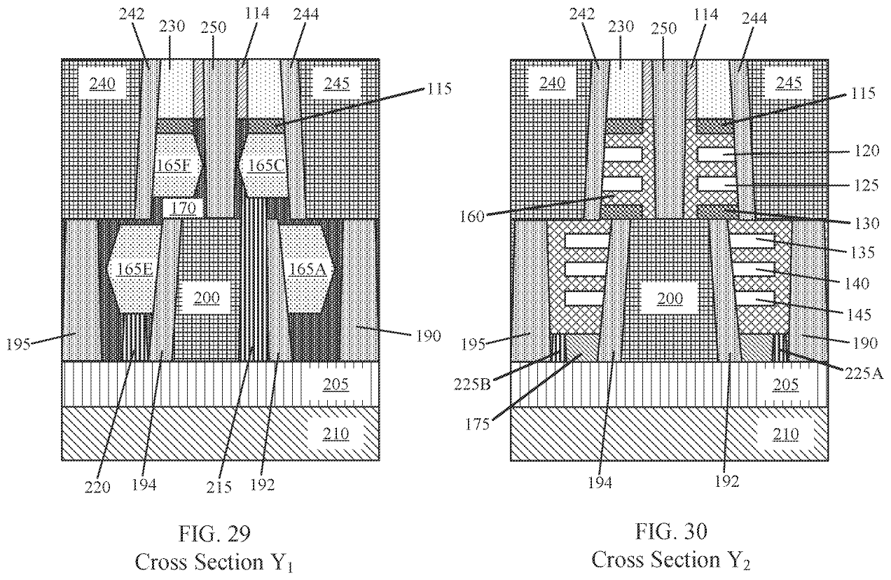

FIGS. 28-30 illustrate cross sections X, Y1, and Y2, respectively, of the plurality of nanodevices ND1, ND2 after the formation of a backside gate cut dielectric pillar 250, a first backside dielectric liner 242, a second backside dielectric liner 244, a first backside dielectric fill 240, and a second backside dielectric fill 245, in accordance with the embodiment of the present invention. A liner material is deposited in the fourth trench 235 to form the backside gate cut dielectric pillar 250. The backside gate cut dielectric pillar 250 is in direct contact with a backside surface of the frontside dielectric fill 200. The liner material is also deposited in the fifth trench 237 and the sixth trench 239 and etched back to form the first backside dielectric liner 242 and the second backside dielectric liner 244, respectively. The first backside dielectric liner 242 and the second backside dielectric liner 244 are located on an inner sidewall of the fifth trench 237 and the sixth trench 239, respectively. The liner material may be comprised of, for example, SiN. In FIGS. 29-30, a portion of the backside gate cut dielectric pillar 250, the first backside dielectric liner 242, and the second backside dielectric liner 244 are selectively removed by, for example, RIE to expose a top surface of the BILD layer 230 and the STI region 114. Then, a dielectric fill material is deposited in the fifth trench 237 and the sixth trench 239 to form the first backside dielectric fill 240 (i.e., the second backside dielectric fill in the claims) and the second backside dielectric fill 245 (i.e., the first backside dielectric fill in the claims), respectively. The first backside dielectric liner 242 and the second backside dielectric liner 244 are located along an inner sidewall of the first backside dielectric fill 240 and an inner sidewall of the second backside dielectric fill 245, respectively. The first frontside dielectric liner 192 and the second backside dielectric liner 244 are offset from each other across the plurality of upper transistors and the plurality of lower transistors. The second frontside dielectric liner 194 and the first backside dielectric liner 242 are offset from each other across the plurality of upper transistors and the plurality of lower transistors. The first backside dielectric fill 240 and the second backside dielectric fill 245 may be comprised of, for example, SiO₂.

Thus, the first frontside dielectric liner 192, the second frontside dielectric liner 194, the first frontside gate cut dielectric pillar 190, the second frontside gate cut dielectric pillar 195, and the backside gate cut dielectric pillar 250 are comprised of a same dielectric material. The first backside dielectric fill 240, the second backside dielectric fill 245, and the frontside dielectric fill 200 are comprised of a different dielectric material. In FIG. 30, the first backside dielectric liner 242 extends along first outer sidewalls of the plurality of lower nanosheets 120, 125, a first outer sidewall of the BDI layer 115, and a first outer sidewall of the MDI layer 130. The second backside dielectric liner 244 extends along second outer sidewalls of the plurality of lower nanosheets 120, 125, a second outer sidewall of BDI layer 115, and a second outer sidewall of the MDI layer 130.

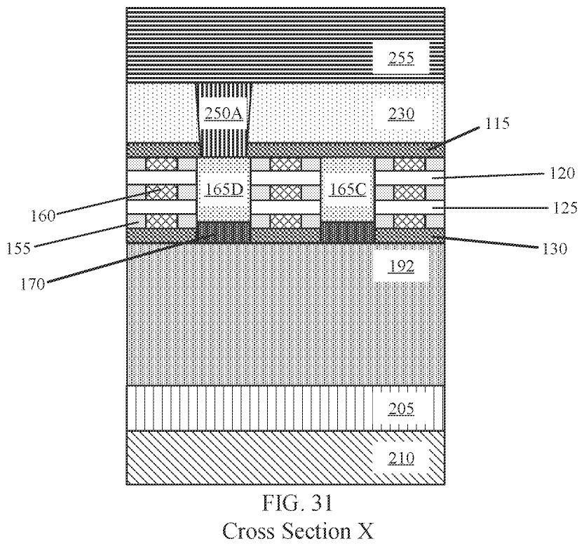

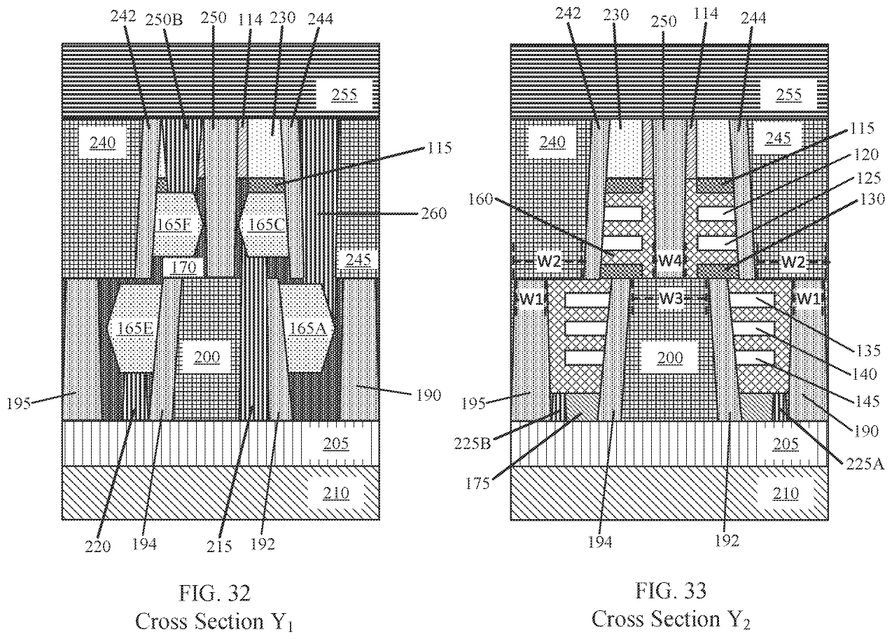

FIGS. 31-33 illustrate cross sections X, Y1, and Y2, respectively, of the plurality of nanodevices ND1, ND2 after the formation of a plurality of backside source/drain contacts 250A, 250B, an upper source/drain contact 260, and a backside power delivery network (BSPDN) 255, in accordance with the embodiment of the present invention. A plurality of trenches (not shown) formed during back-end-of-line (BEOL) patterning are filled with a conductive metal (e.g., including a silicide liner, such as Ni, Ti, NiPt, an adhesion metal liner, such as TiN and conductive metal fill, such as W, Co, or Ru) to form the plurality of backside source/drain contacts 250A, 250B and the upper source/drain contact 260. In FIG. 31, the first backside source/drain contact 250A is located directly atop the second lower source/drain 165D. In FIG. 32, the second backside source/drain contact 250B is located directly atop the third lower source/drain 165F. The upper source/drain contact 260 extends downwards from a backside of the plurality of nanodevices ND1, ND2 to connect to a backside of the first upper source/drain 165A. The lower source/drain contact 215 extends upwards from a frontside of the plurality of nanodevices ND1, ND2 to connect to a frontside of the first lower source/drain 165C. In FIG. 31, the BSPDN 255 is formed directly atop the BILD layer 230 and the first backside source/drain contact 250A. In FIG. 32, the BSPDN 255 is formed directly atop the backside gate cut dielectric pillar 250, the BILD layer 230, the first backside dielectric fill 240, the second backside dielectric fill 245, the first backside dielectric liner 242, the second backside dielectric liner 244, the STI region 114, the second backside source/drain contact 250B, and the upper source/drain contact 260. In FIG. 33, the BSPDN 255 is formed directly atop the backside gate cut dielectric pillar 250, the BILD layer 230, the first backside dielectric fill 240, the second backside dielectric fill 245, the first backside dielectric liner 242, the second backside dielectric liner 244, and the STI region 114.

In FIGS. 31-33, the plurality of nanodevices include an upper active region and a lower active region that are offset from each other across the plurality of upper transistors and the plurality of lower transistors. The upper active region includes the plurality of upper nanosheets 135, 140, 145, the first upper source/drain 165A, the second upper source/drain 165B, and the third upper source/drain 165E. The lower active region includes the plurality of lower nanosheets 120, 125, the first lower source/drain 165C, the second lower source/drain 165D, and the third lower source/drain 165F. The plurality of upper nanosheets 135, 140, 145 are located closer to the first frontside gate cut dielectric pillar 190 than the plurality of lower nanosheets 120, 125. The plurality of upper nanosheets 135, 140, 145 and the plurality of lower nanosheets 120, 125 are offset from each other across the plurality of upper transistors and the plurality of lower transistors. The first upper source/drain 165A and the first lower source/drain 165C are offset from each other across the plurality of upper transistors and the plurality of lower transistors. The first upper source/drain 165A is in direct contact with an outer sidewall of the first frontside dielectric liner 192. The first lower source/drain 165C is in direct contact with an inner sidewall of the second backside dielectric liner 244.

A backside surface of the first frontside gate cut dielectric pillar 190 extends a first width W1 along the y-axis. A backside surface of the second frontside gate cut dielectric pillar 195 also extends the first width W1 along the y-axis. The second backside dielectric fill 245 is in direct contact with the backside surface of the first frontside gate cut dielectric pillar 190. The first backside dielectric fill 240 is in direct contact with the backside surface of the second frontside gate cut dielectric pillar 195. A frontside surface of the first backside dielectric fill 240 and a frontside surface of the second backside dielectric fill 245 each extend a second width W2 along the y-axis. The second width W2 is greater than the first width W1.

The first frontside gate cut dielectric pillar 190 and the backside gate cut dielectric pillar 250 are offset from each other across the plurality of upper transistors and the plurality of lower transistors. The second frontside gate cut dielectric pillar 195 and the backside gate cut dielectric pillar 250 are also offset from each other across the plurality of upper transistors and the plurality of lower transistors. The frontside dielectric fill 200 and the first backside dielectric fill 240 are offset from each other across the plurality of upper transistors and the plurality of lower transistors. The frontside dielectric fill 200 and the second backside dielectric fill 245 are also offset from each other across the plurality of upper transistors and the plurality of lower transistors. A backside surface of the frontside dielectric fill 200 extends a third width W3 along the y-axis. A frontside surface of the backside gate cut dielectric pillar 250 extends a fourth width W4 along the y-axis. The third width W3 is greater than the fourth width W4.

The plurality of nanodevices ND1, ND2 include the upper active region and the lower active region that are offset from each other across the plurality of upper transistors and the plurality of lower transistors. The backside surface of the first frontside gate cut dielectric pillar 190 extends the first width W1 along the y-axis. The frontside surface of the second backside dielectric fill 245 extends the second width W2 along the y-axis. The second width W2 is greater than the first width W1. The first frontside gate cut dielectric pillar 190 and the second backside dielectric fill 245 are comprised of a different dielectric material.

It may be appreciated that FIGS. 1-33 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a plurality of nanodevices including a plurality of upper transistors and a plurality of lower transistors, wherein the plurality of nanodevices include an upper active region and a lower active region that are offset from each other across the plurality of upper transistors and the plurality of lower transistors;
a first frontside gate cut dielectric pillar located adjacent to and parallel to a first nanodevice of the plurality of nanodevices along an x-axis, wherein a backside surface of the first frontside gate cut dielectric pillar extends a first width along a y-axis; and
a first backside dielectric fill in direct contact with the backside surface of the first frontside gate cut dielectric pillar, wherein a frontside surface of the first backside dielectric fill extends a second width along the y-axis, and wherein the second width is greater than the first width.

2. The semiconductor device of claim 1, wherein the upper active region includes a plurality of upper nanosheets and the lower active region includes a plurality of lower nanosheets, wherein the plurality of upper nanosheets are located closer to the first frontside gate cut dielectric pillar than the plurality of lower nanosheets.

3. The semiconductor device of claim 2, wherein the plurality of upper nanosheets and the plurality of lower nanosheets are offset from each other across the plurality of upper transistors and the plurality of lower transistors.

4. The semiconductor device of claim 3, further comprising:
a first frontside dielectric liner extending along first inner sidewalls of the plurality of upper nanosheets and a second frontside dielectric liner extending along second inner sidewalls of the plurality of upper nanosheets; and
a frontside dielectric fill located between the first frontside dielectric liner and the second frontside dielectric liner.

5. The semiconductor device of claim 4, further comprising:
a backside gate cut dielectric pillar in direct contact with a backside surface of the frontside dielectric fill.

6. The semiconductor device of claim 5, wherein the first frontside dielectric liner, the second frontside dielectric liner, the first frontside gate cut dielectric pillar, and the backside gate cut dielectric pillar are comprised of a same dielectric material, and wherein the first backside dielectric fill and the frontside dielectric fill are comprised of a different dielectric material.

7. The semiconductor device of claim 6, wherein the first frontside gate cut dielectric pillar and the backside gate cut dielectric pillar are offset from each other across the plurality of upper transistors and the plurality of lower transistors.

8. The semiconductor device of claim 7, wherein the backside surface of the frontside dielectric fill extends a third width along the y-axis, wherein a frontside surface of the backside gate cut dielectric pillar extends a fourth width along the y-axis, and wherein the third width is greater than the fourth width.

9. A semiconductor device comprising:
a plurality of nanodevices including a plurality of upper transistors and a plurality of lower transistors, wherein the plurality of nanodevices include an upper active region and a lower active region that are offset from each other across the plurality of upper transistors and the plurality of lower transistors;
a first frontside gate cut dielectric pillar and a second frontside gate cut dielectric pillar located adjacent to and parallel to a first nanodevice and a second nanodevice, respectively, of the plurality of nanodevices along an x-axis, wherein a backside surface of the first frontside gate cut dielectric pillar and a backside surface of the second frontside gate cut dielectric pillar each extend a first width along a y-axis; and
a first backside dielectric fill and a second backside dielectric fill in direct contact with the backside surface of the first frontside gate cut dielectric pillar and the backside surface of the second frontside gate cut dielectric pillar, respectively, wherein a frontside surface of the first backside dielectric fill and a frontside surface of the second backside dielectric fill each extend a second width along the y-axis, and wherein the second width is greater than the first width.

10. The semiconductor device of claim 9, wherein the upper active region includes a plurality of upper nanosheets and the lower active region includes a plurality of lower nanosheets, wherein the plurality of upper nanosheets are located closer to the first frontside gate cut dielectric pillar than the plurality of lower nanosheets.

11. The semiconductor device of claim 10, wherein the plurality of upper nanosheets and the plurality of lower nanosheets are offset from each other across the plurality of upper transistors and the plurality of lower transistors.

12. The semiconductor device of claim 11, further comprising:
a first frontside dielectric liner extending along first inner sidewalls of the plurality of upper nanosheets and a second frontside dielectric liner extending along second inner sidewalls of the plurality of upper nanosheets; and
a frontside dielectric fill located between the first frontside dielectric liner and the second frontside dielectric liner.

13. The semiconductor device of claim 12, further comprising:
a backside gate cut dielectric pillar in direct contact with a backside surface of the frontside dielectric fill; and
a first backside dielectric liner and a second backside dielectric liner located along an inner sidewall of the second backside dielectric fill and an inner sidewall of the first backside dielectric fill, respectively, wherein the first frontside dielectric liner and the second backside dielectric liner are offset from each other across the plurality of upper transistors and the plurality of lower transistors, and wherein the second frontside dielectric liner and the first backside dielectric liner are offset from each other across the plurality of upper transistors and the plurality of lower transistors.

14. The semiconductor device of claim 13, wherein the first frontside dielectric liner, the second frontside dielectric liner, the first frontside gate cut dielectric pillar, the second frontside gate cut dielectric pillar, the first backside gate cut dielectric pillar, the second backside gate cut dielectric pillar, and the backside gate cut dielectric pillar are comprised of a same dielectric material, and wherein the first backside dielectric fill, the second backside dielectric fill, and the frontside dielectric fill are comprised of a different dielectric material.

15. The semiconductor device of claim 14, wherein the frontside dielectric fill and the first backside dielectric fill are offset from each other across the plurality of upper transistors and the plurality of lower transistors, and wherein the frontside dielectric fill and the second backside dielectric fill are offset from each other across the plurality of upper transistors and the plurality of lower transistors.

16. The semiconductor device of claim 15, wherein the first frontside gate cut dielectric pillar and the backside gate cut dielectric pillar are offset from each other across the plurality of upper transistors and the plurality of lower transistors, and wherein the second frontside gate cut dielectric pillar and the backside gate cut dielectric pillar are offset from each other across the plurality of upper transistors and the plurality of lower transistors.

17. A semiconductor device comprising:
a plurality of nanodevices including a plurality of upper transistors and a plurality of lower transistors, wherein the plurality of nanodevices include an upper active region and a lower active region that are offset from each other across the plurality of upper transistors and the plurality of lower transistors, wherein the upper active region includes an upper source/drain, and wherein the lower active region includes a lower source/drain;
a first frontside gate cut dielectric pillar and a second frontside gate cut dielectric pillar located adjacent to and parallel to a first nanodevice and a second nanodevice, respectively, of the plurality of nanodevices along an x-axis, wherein a backside surface of the first frontside gate cut dielectric pillar and a backside surface of the second frontside gate cut dielectric pillar each extend a first width along a y-axis; and
a first backside dielectric fill and a second backside dielectric fill in direct contact with the backside surface of the first frontside gate cut dielectric pillar and the backside surface of the second frontside gate cut dielectric pillar, respectively, wherein a frontside surface of the first backside dielectric fill and a frontside surface of the second backside dielectric fill each extend a second width along the y-axis, and wherein the second width is greater than the first width.

18. The semiconductor device of claim 17, wherein the upper source/drain and the lower source/drain are offset from each other across the plurality of upper transistors and the plurality of lower transistors.

19. The semiconductor device of claim 18, wherein the upper active region further includes a plurality of upper nanosheets and the lower active region further includes a plurality of lower nanosheets, wherein the plurality of upper nanosheets are located closer to the first frontside gate cut dielectric pillar than the plurality of lower nanosheets.

20. The semiconductor device of claim 19, wherein the plurality of upper nanosheets and the plurality of lower nanosheets are offset from each other across the plurality of upper transistors and the plurality of lower transistors.

21. The semiconductor device of claim 20, further comprising:
a first frontside dielectric liner extending along first inner sidewalls of the plurality of upper nanosheets and a second frontside dielectric liner extending along second inner sidewalls of the plurality of upper nanosheets; and
a frontside dielectric fill located between the first frontside dielectric liner and the second frontside dielectric liner.

22. The semiconductor device of claim 21, further comprising:
a backside gate cut dielectric pillar in direct contact with a backside surface of the frontside dielectric fill; and
a first backside dielectric liner and a second backside dielectric liner located along an inner sidewall of the second backside dielectric fill and an inner sidewall of the first backside dielectric fill, respectively, wherein the first frontside dielectric liner and the second backside dielectric liner are offset from each other across the plurality of upper transistors and the plurality of lower transistors, and wherein the second frontside dielectric liner and the first backside dielectric liner are offset from each other across the plurality of upper transistors and the plurality of lower transistors.

23. The semiconductor device of claim 22, wherein the upper source/drain is in direct contact with an outer sidewall of the first frontside dielectric liner, and wherein the lower source/drain is in direct contact with an inner sidewall of the second backside dielectric liner.

24. A semiconductor device comprising:
a plurality of nanodevices including a plurality of upper transistors and a plurality of lower transistors, wherein the plurality of nanodevices include an upper active region and a lower active region that are offset from each other across the plurality of upper transistors and the plurality of lower transistors, wherein the upper active region includes an upper source/drain, and wherein the lower active region includes a lower source/drain;
an upper source/drain contact and a lower source/drain contact connected to the upper source/drain and the lower source/drain, respectively;
a first frontside gate cut dielectric pillar and a second frontside gate cut dielectric pillar located adjacent to and parallel to a first nanodevice and a second nanodevice, respectively, of the plurality of nanodevices along an x-axis, wherein a backside surface of the first frontside gate cut dielectric pillar and a backside surface of the second frontside gate cut dielectric pillar each extend a first width along a y-axis; and
a first backside dielectric fill and a second backside dielectric fill in direct contact with the backside surface of the first frontside gate cut dielectric pillar and the backside surface of the second frontside gate cut dielectric pillar, respectively, wherein a frontside surface of the first backside dielectric fill and a frontside surface of the second backside dielectric fill each extend a second width along the y-axis, and wherein the second width is greater than the first width.

25. The semiconductor device of claim 24, wherein the upper source/drain contact extends downwards from a backside of the plurality of nanodevices to connect to a backside of the upper source/drain, and wherein the lower source/drain contact extends upwards from a frontside of the plurality of nanodevices to connect to a frontside of the lower source/drain.
